(19) United States
(12) Patent Application Publication
(10) Pub. No.: US 2008/0132036 A1
(43) Pub. Date: Jun. 5, 2008

(54) Method for subdividing wafer into LEDs

(76) Inventor: Chiu Chung Yang, Taichung (TW)

Correspondence Address: CHARLES E. BAXLEY, ESQ., 90 JOHN STREET, THIRD FLOOR, NEW YORK, NY, 10038, US

(21) Appl. No.: 11/633,608

(22) Filed: Dec. 4, 2006

(51) Int. Cl. H01L 21/00

(52) U.S. Cl. 438/465

(57) ABSTRACT

A method for forming chips on a wafer includes forming one or more spaces in a substrate to form and to space two or more chips from each other, forming a positive electrode and a negative electrode in each of the chips, cutting one or more cut-off portions through the substrate and communicating with the space of the substrate. A protective layer is applied onto the outer peripheral portion of the substrate and the chips and includes a covering portion engaged into the cut-off portion of the substrate for allowing the substrate and the chips to be completely shielded and protected by the protective layer without further sealing or packaging operations.

### BACKGROUND OF THE INVENTION

1. Field of the Invention

The present invention relates to a wafer subdividing method, and more particularly to a wafer subdividing method for subdividing a wafer into a number of chips or light emitting diodes (LEDs) and for allowing the chips or LEDs to be suitably sealed or protected by an outer protective layer and to be prevented from being wetted or damaged by humidity.

2. Description of the Prior Art

Typical chips or light emitting diodes (LEDs) are made separately and include one or more legs or prongs engaged through a circuit board and secured to the circuit board with such as a welding process. However, it takes time and it is complicated to attach the chips or LEDs onto the circuit board and to secure the chips or LEDs onto the circuit board.

The other typical chips or light emitting diodes (LEDs) may be attached or secured to the circuit board with such as adhesive materials or by such as a sealing package.

For facilitating the formation or the attachment of the chips or LEDs on the circuit board, the other methods have been developed for directly forming the chips or LEDs on the circuit board. For example, U.S. Pat. No. 6,713,843 to Fu discloses one of the typical methods for forming or dicing the chips or dies on a wafer, and for providing scribe lines for increasing a wafer utilizable area, and for allowing the wafer to be diced into a number of individual dies.

However, the scribe lines are close to each other such that the chips or dies may not be suitably sealed or protected with an outer covering, or the outer covering may not be suitably applied onto the chips or dies for completely shielding and protecting the chips or dies.

U.S. Pat. No. 6,833,284 to Göltl et al. discloses another typical method for subdividing wafers into chips and comprising a water including a substrate and an epitaxial layer and a number of successively grown semiconductor layers. A number of slot-like recesses are required to be introduced into the wafer which will then be applied to a carrier sheet, and the carrier sheet may pull the wafer over breaking wedges which may subdivide the wafer into individual chips.

However, after the wafer is subdivided into individual chips by the breaking wedges, the breaking portions of the individual chips will be exposed and may not be suitably sealed or protected with an outer covering such that the formed individual chips may not be suitably sealed and packaged.

U.S. Pat. No. 6,946,729 to Lee et al. discloses a further typical wafer level package structure comprising a heat slug metal which is required to be formed with a number of openings and which is then required to be mounted onto a wafer to dispose the openings of the heat slug metal on corresponding bonding pads of the wafer to as to expose the bonding pads, and the combined heat slug metal and the wafer will then be sawed into a number of die units.

However, similarly, after the combined heat slug metal and the wafer are sawed or subdivided into the die units, the breaking portions of the die units will also be exposed and may not be suitably sealed or protected with an outer protective covering such that the thus formed or made die units may not be suitably sealed and packaged.

The present invention has arisen to mitigate and/or obviate the afore-described disadvantages of the conventional methods for subdividing the wafers into a number of individual chips or LEDs or die units.

### SUMMARY OF THE INVENTION

The primary objective of the present invention is to provide a wafer subdividing method for subdividing a wafer into a number of chips or light emitting diodes (LEDs) and for allowing the chips or LEDs to be suitably sealed or protected or shielded by an outer protective layer and to be prevented from being wetted or damaged by such as humidity.

In accordance with one aspect of the invention, there is provided a method for forming chips on a wafer, the wafer including a substrate disposed on a carrier layer, and a plurality of semiconductor layers provided on the substrate, the method comprising forming at least one space in the substrate to form a first chip and at least one second chip in the substrate and to space the first chip and the second chip from each other, forming a positive electrode and a negative electrode in each of the first chip and the second chip, cutting at least one cut-off portion through the substrate, and the cut-off portion being communicating with the space of the substrate for allowing the first chip and the second chip to be spaced from each other, applying a protective layer onto an outer peripheral portion of the substrate and the first chip and the second chip, the protective layer including a covering portion engaged into the cut-off portion of the substrate and applied onto the outer peripheral portion of the substrate and the first chip and the second chip for allowing the substrate and the first chip and the second chip to be completely shielded and protected by the protective layer, and separating the first chip and the second chip from each other. The chips thus formed may be suitably or completely sealed or protected or shielded by the outer protective layer and may be prevented from being wetted or damaged by such as humidity.

The cut-off portion is preferably formed through a depth of the substrate, or is preferably partially formed into the carrier layer for allowing the chips to be easily bent or disengaged from each other. The cut notch may be partially cut or formed into the carrier layer. The protective layer is preferably made of translucent and insulated materials.

The carrier layer may further be cut to form one or more cut notches which are communicating with the cut-off portion of the substrate for allowing the carrier layer to be broken at the cut notches and for allowing the first chip and the second chip to be easily bent or separated or disengaged from each other to form individual chips.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a block diagram illustrating the processes of a method in accordance with the present invention;

FIGS. 2, 3, 4, 5 are partial plan schematic views illustrating the manufacturing processes for forming or making a number of chips or die units or LEDs on a wafer;

FIG. 6 is a partial plan schematic view similar to FIGS. 2-5, illustrating a single chip or die unit or LED formed by the method in accordance with the present invention;

FIGS. 7, 8 are partial plan schematic views similar to FIGS. 2-5, illustrating the other arrangement for forming or making the chips or die units or LEDs on the wafer; and

FIG. 9 is a partial plan schematic view similar to FIG. 7-8, illustrating a single chip or die unit or LED formed by the arrangement as shown in FIGS. 7-8.

### DETAILED DESCRIPTION OF THE PREFERRED EMBODIMENT

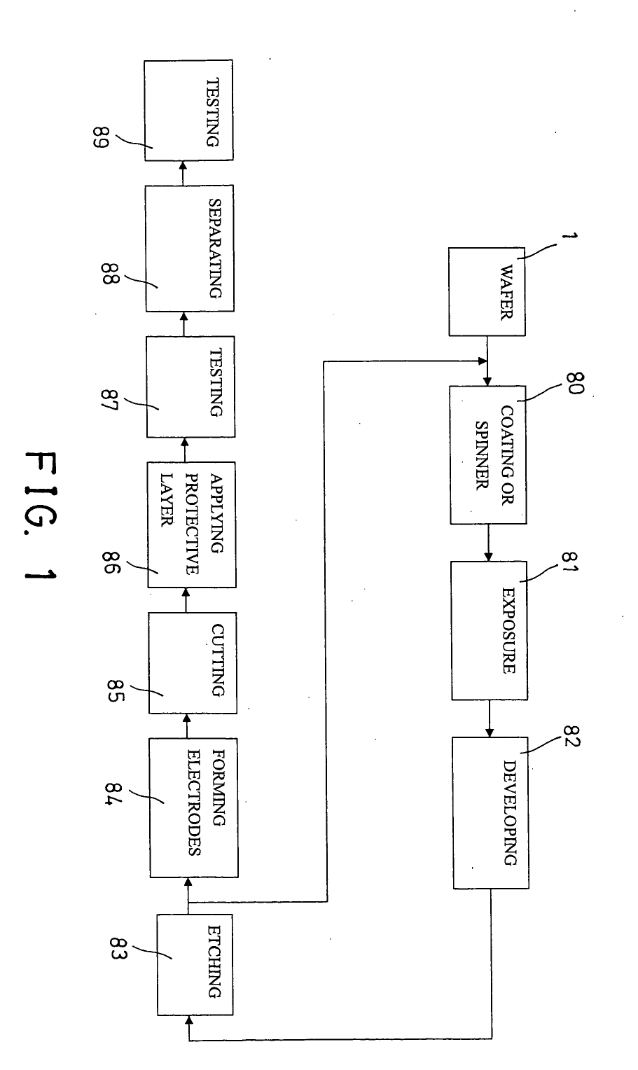

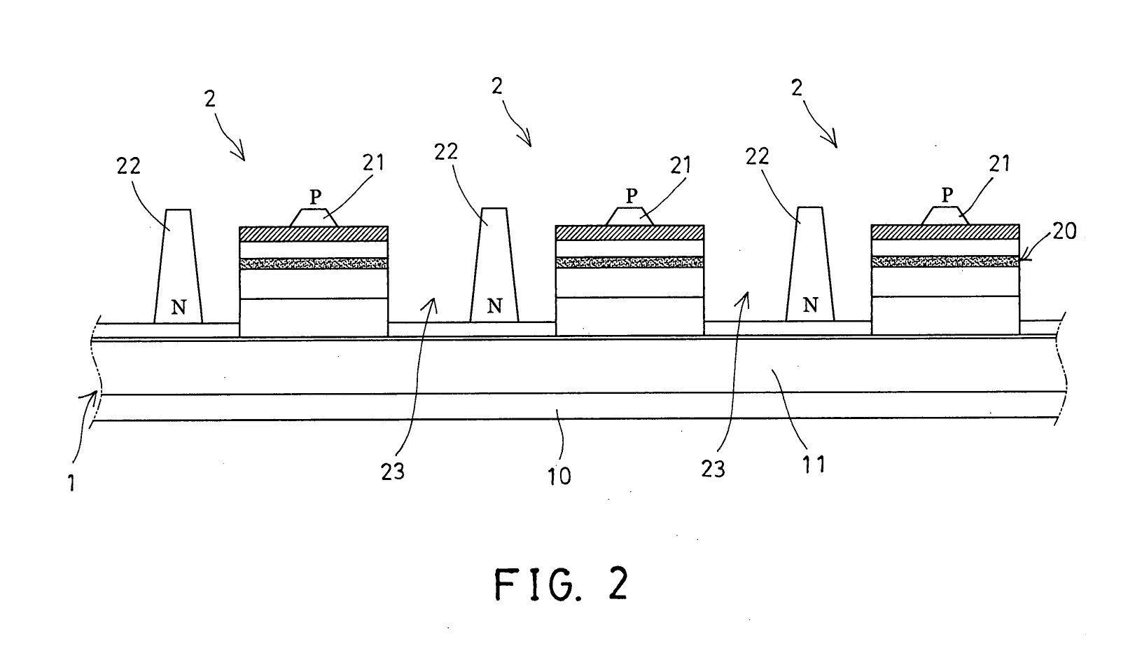

Referring to the drawings, and initially to FIGS. 1 and 2, a method in accordance with the present invention comprises providing a wafer 1 including a substrate 11 provided and disposed on an epitaxial or carrier layer 10, and a number of successively grown semiconductor layers 20 provided or formed on the substrate 11. The precise layer sequence depends on the functionality respectively envisaged for the carrier layer 10. The present invention is provided for application in the production of individual chips or light emitting diodes (LEDs) or die units, particularly the LEDs 2 as shown in FIGS. 2-9.

The wafer 1 will be subjected or conducted with various manufacturing procedures, as shown in FIG. 1, such as a coating or spinner process 80, an exposure process 81, and/or a developing process 82, and/or an etching process 83, for making or forming the electrodes 21, 22, such as the positive electrodes (P) 21 and the negative electrodes (N) 22 in an electrode forming process 84, and for making or forming one or more spaces 23 in the upper portion of the substrate 11 (FIG. 2), in order to separate two or more pairs of positive (P) and negative electrodes (N) 21, 22 from each other and for forming two or more chips or die units or LEDs 2. It is to be noted that the spaces 23 are only formed in the upper portion of the substrate 11 (FIG. 2) but not completely formed through the substrate 11 at this moment. The coating or spinner process 80 and the exposure process 81 and the developing process 82 and the etching process 83 are not related to the present invention and will not be described in further details.

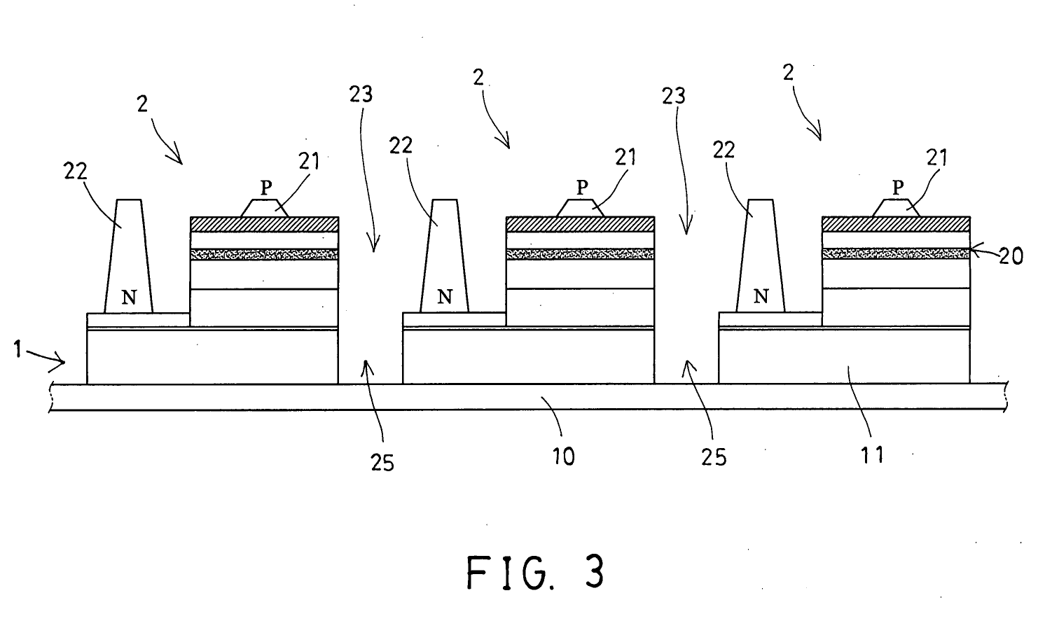

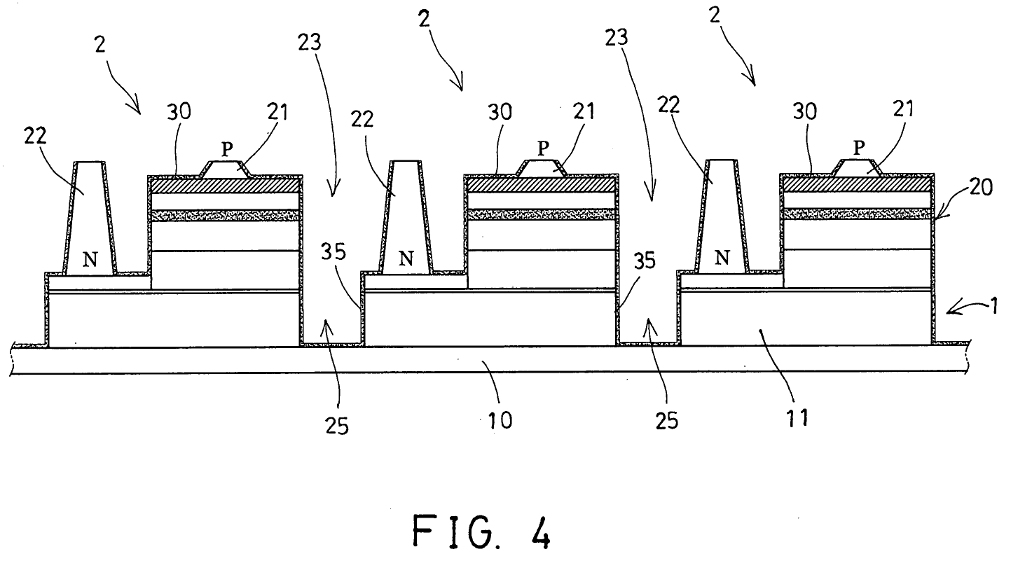

As shown in FIG. 3, the substrate 11 will then be subjected or conducted with a cutting procedure 85 in order to form or to make one or more cut-off portions 25 through the depth of the substrate 11, and the cut-off portions 25 are aligned with or communicating with the spaces 23 of the substrate 11 for allowing the chips or die units or LEDs 2 to be suitably separated or spaced from each other. As shown in FIG. 4, the substrate 11 and the chips or die units or LEDs 2 will then be subjected or conducted with a protective layer applying procedure 86 in order to apply the protective layer 30 onto the outer peripheral portion of the substrate 11 and the chips or die units or LEDs 2, in which the protective layer 30 includes a covering portion 35 engaged into the cut-off portions 25 of the substrate 11 and applied onto the outer peripheral portion of the substrate 11 for allowing the substrate 11 and the chips or die units or LEDs 2 to be suitably and completely shielded and protected and sealed by the protective layer 30.

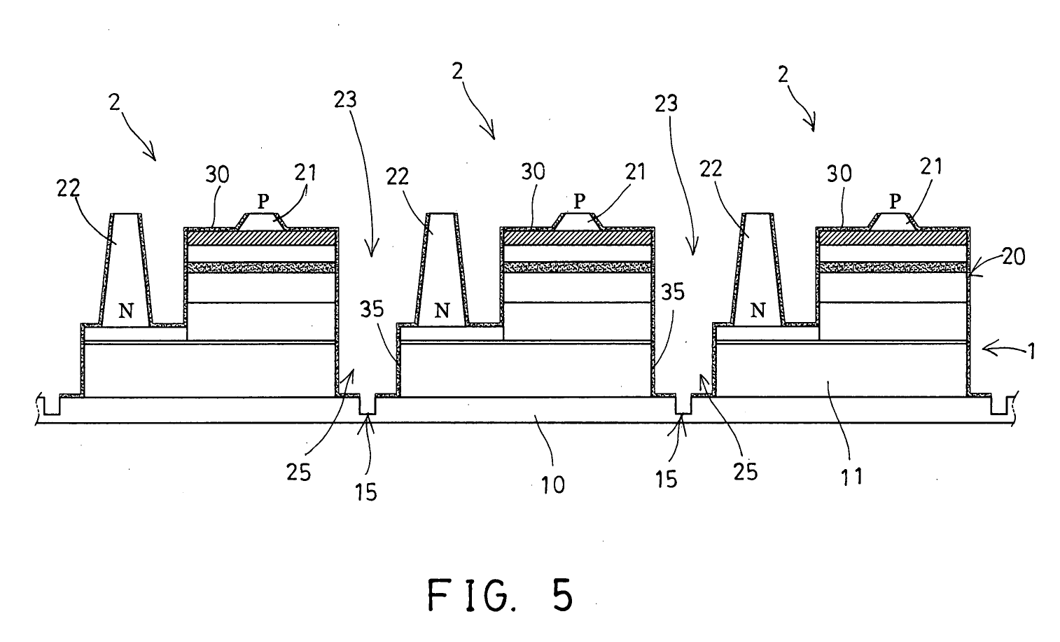

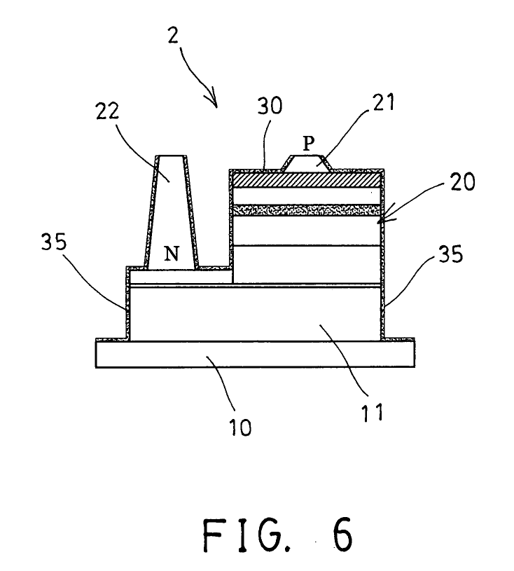

The substrate 11 and the chips or die units or LEDs 2 will then be subjected or conducted with a testing procedure 87 in order to test or to examine whether the chips or die units or LEDs 2 are well made or formed or not. If the chips or die units or LEDs 2 have been checked or examined to be well made or formed, the substrate 11 and the chips or die units or LEDs 2 will then be subjected or conducted with a cutting or separating procedure 88 in order to partially cut or form one or more cut notches 15 within the carrier layer 10 and aligned with or communicating with the cut-off portions 25 of the substrate 11 (FIG. 5) for allowing the carrier layer 10 to be easily bent and broken at the cut notches 15 and for allowing the chips or die units or LEDs 2 to be suitably separated or disengaged from each other to form the individual LED 2 as shown in FIG. 6.

It is to be noted that, as shown in FIGS. 5 and 6, the protective layer 30 may be suitably and completely applied onto and around the outer peripheral portion of the substrate 11 and the chips or die units or LEDs 2 for preventing the substrate 11 and the chips or die units or LEDs 2 from being wetted or damaged by humidity, and for preventing the chips or LEDs 2 from being oxidized or rusted, and for preventing the chips or LEDs 2 from being electrically contacted with the other electrical parts or elements. The protective layer 30 may be made of transparent or translucent and non-conductive or insulated materials. The formed individual chips or LEDs 2 may then be subjected or conducted with another testing procedure 89 in order to test or to examine whether the chips or die units or LEDs 2 are operated or functioned well or not, and may then be directly attached or secured onto the circuit boards (not shown) without further sealing or packaging processes.

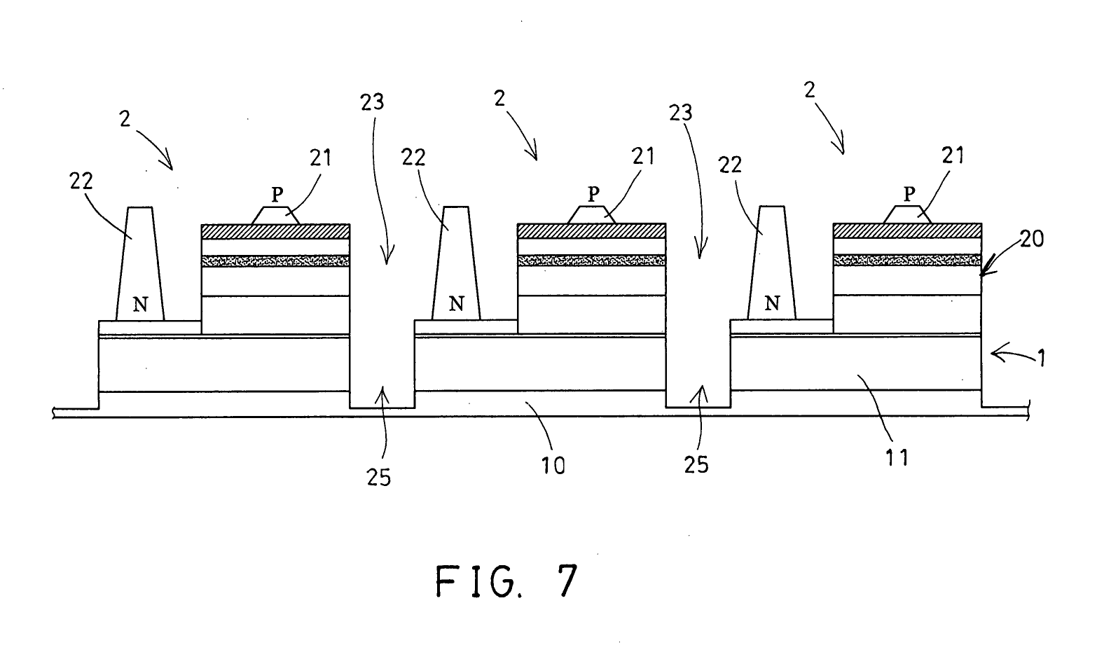

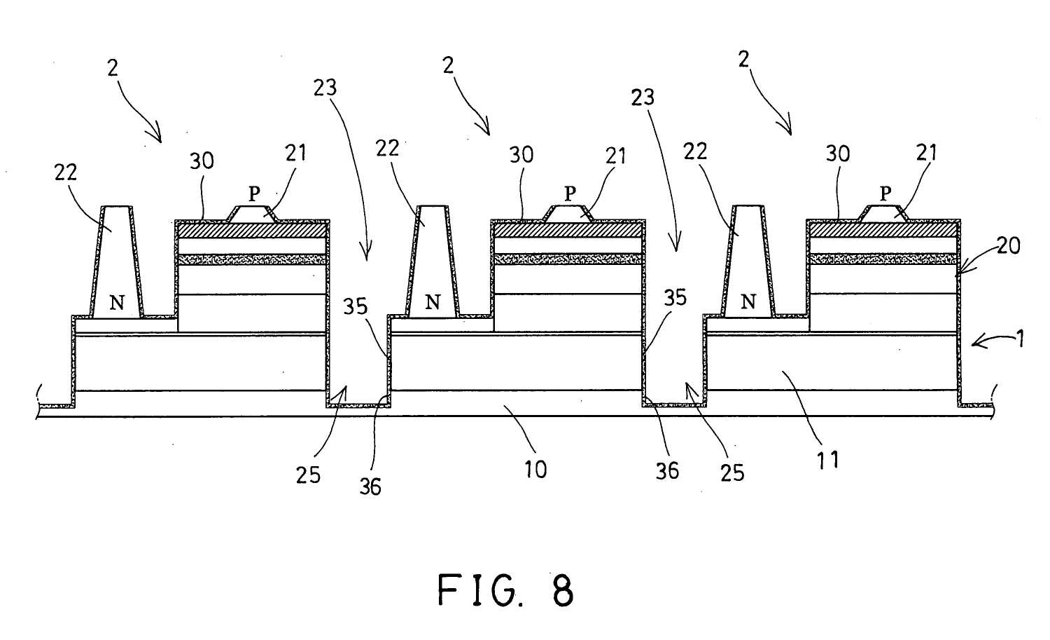

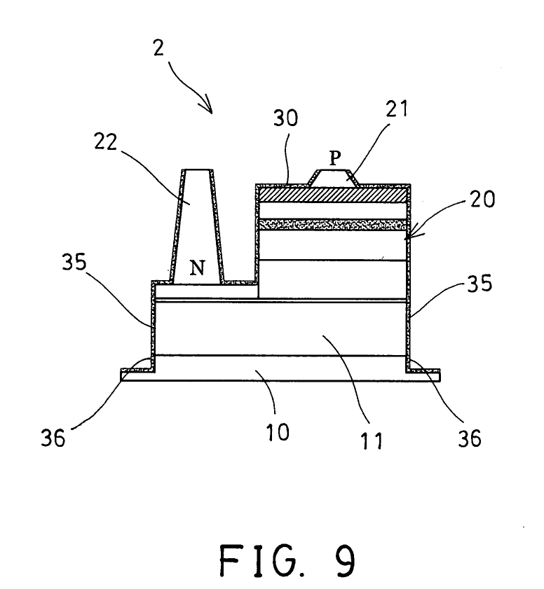

Alternatively, as shown in FIGS. 7 and 8, in the cutting procedure 85, the cut-off portions 25 may also be formed through the depth of the substrate 11 and may further be directly and partially cut or formed into the carrier layer 10 and aligned with or communicating with the spaces 23 of the substrate 11 without forming or instead of the cut notches 15 of the carrier layer 10, and the protective layer 30 may include another covering portion 36 engaged into the cut-off portions 25 of the substrate 11 and applied onto the outer peripheral portion of the carrier layer 10 for allowing the substrate 11 and the chips or LEDs 2 to be suitably and completely shielded and protected and sealed by the protective layer 30, and for allowing the substrate 11 and the chips or LEDs 2 to be suitably and directly separated or disengaged from each other to form the individual LED 2 as shown in FIG. 9.

Similarly, as shown in FIGS. 8 and 9, the protective layer 30 may also be suitably and completely applied onto and around the outer peripheral portion of the substrate 11 and the chips or LEDs 2 and a portion of the carrier layer 10 for preventing the substrate 11 and the chips or die units or LEDs 2 from being wetted or damaged by humidity, and for preventing the chips or LEDs 2 from being oxidized or rusted, and for preventing the chips or LEDs 2 from being electrically contacted with the other electrical parts or elements. The individual chips or LEDs 2 may then be directly attached or secured onto the circuit boards (not shown) without further sealing or packaging processes.

Accordingly, the wafer subdividing method in accordance with the present invention may be provided for subdividing the wafer into a number of chips or LEDs and for allowing the chips or LEDs to be suitably sealed or protected or shielded by the outer protective layer and to be and prevented from being wetted or damaged by humidity.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A method for forming chips on a wafer, said wafer including a substrate disposed on a carrier layer, and a plurality of semiconductor layers provided on said substrate, said method comprising:
forming at least one space in said substrate to form a first chip and at least one second chip in said substrate and to space said first chip and said at least one second chip from each other,
forming a positive electrode and a negative electrode in each of said first chip and said at least one second chip,
cutting at least one cut-off portion through said substrate, and said at least one cut-off portion being communicating with said at least one space of said substrate for allowing said first chip and said at least one second chip to be spaced from each other,
applying a protective layer onto an outer peripheral portion of said substrate and said first chip and said at least one second chip, said protective layer including a covering portion engaged into said at least one cut-off portion of said substrate and applied onto the outer peripheral portion of said substrate and said first chip and said at least one second chip for allowing said substrate and said first chip and said at least one second chip to be completely shielded and protected by said protective layer, and
separating said first chip and said at least one second chip from each other.

2. The method as claimed in claim 1, wherein said at least one cut-off portion is formed through a depth of said substrate.

3. The method as claimed in claim 1, wherein said at least one cut-off portion is partially formed into said carrier layer.

4. The method as claimed in claim 1 further comprising cutting at least one cut notch in said carrier layer and communicating with said at least one cut-off portion of said substrate for allowing said carrier layer to be broken at said at least one cut notch and for allowing said first chip and said at least one second chip to be disengaged from each other to form individual chips.

5. The method as claimed in claim 4, wherein said at least one cut notch is partially formed in said carrier layer.

6. The method as claimed in claim 1, wherein said protective layer is made of translucent and insulated materials.
